(19) United States
(12) Patent Application Publication
(10) Pub. No.: US 2006/0172062 A1
(43) Pub. Date: Aug. 3, 2006

(54) Method for manufacturing a plating seed layer of electronic elements

(76) Inventor: Mu-Yuan Chen, Taipei (TW)

Correspondence Address: RABIN & BERDO, P.C., Suite 500, 1101 14 Street, N.W., Washington, DC, 20005, US

(21) Appl. No.: 11/043,928

(22) Filed: Jan. 28, 2005

(51) Int. Cl. B05D 5/12; C23C 14/32; C23C 16/00

(52) U.S. Cl. 427/58; 204/192.11; 427/248.1; 204/192.1

(57) ABSTRACT

A method for manufacturing a plating seed layer of electronic elements uses a guiding plate to direct one or more electronic element into insertion holes of a holding plate. Each of the insertion holes has an elastic member to hold the electronic element firmly with two ends thereof exposed outside the holding plate. Finally, a metal film is formed on the surfaces of the two ends of the electronic element through a semiconductor manufacturing process (such as sputtering, vapor vaporization, or the like) to become the seed layer required for plating.

### FIELD OF THE INVENTION

The present invention relates to a method for manufacturing a plating seed layer of electronic elements adopted for use in forming a plating seed layer on the surfaces of multi-layer ceramic electronic elements.

### BACKGROUND OF THE INVENTION

With rapid growth of wireless communication market in recent years, mobile communication products have become smaller, lighter and more densely packaged to meet the consumer's demand. To comply with this trend, the conventional passive elements (such as inductors, capacitors and resistors) also are miniaturized and fabricated in a thinner and multilayer fashion. As ceramic material, having excellent high frequency characteristics, low temperature cofired ceramics (LTCC) has become very popular in the communication electronics.

In the process for fabricating passive elements based on multilayer ceramics, a metal layer has to be plated on the surface to serve as electric contacts. To do plating, a seed layer has to be formed on the surface of the element where plating is to be done. The fabricating process for forming the seed layer is quite tedious.

Refer to FIGS. 1A, 1B and 1C for a conventional process for manufacturing a seed layer used in plating to form a multilayer ceramic capacitor (MLCC).

As shown in FIG. 1A, a glass fiber substrate 10 is provided that has a plurality of insertion holes 11. The glass fiber substrate 10 has one side adhering to an adhesive fabric 20. Electronic elements 30 are inserted into the insertion holes 11 and exposed to form a surface 31 that serves as a plating seed layer.

Referring to FIG. 1B, the entire glass fiber substrate 10 is turned 180 degrees to dip the surface of the elements 30 into a solution with a metal solution such as silver, copper or the like to coat a layer of metal on the surface 31.

Referring to FIG. 1C, the adhesive fabric 20 bonded to the glass fiber substrate 10 is removed. And the entire glass fiber substrate 10 and the electronic elements 30 are pre-heated to make the metal adhering firmly to the surface 31 to form a seed layer 32 for a plating process.

The processes set forth above form the seed layer 32 only on one surface 31 of the electronic elements 30. If the seed layer has to be formed on another surface of the electronic elements 31, the processes of FIGS. 1A through 1C have to be repeated. Hence the processes are tedious, and a great amount of costs has to be invested in the manufacturing equipment.

Therefore to simplify the entire manufacturing process with less equipment to form seed layers on the surfaces of electronic elements is a technical issue remained to be overcome.

### SUMMARY OF THE INVENTION

In view of the aforesaid problems, the primary object of the present invention is to provide a method for manufacturing a plating seed layer of electronic elements made from multi layer ceramics (such as capacitors, inductors, resistors or the like) to overcome the disadvantages of conventional techniques.

To achieve the foregoing object, the method for manufacturing a plating seed layer of electronic elements, first, provides a holding plate, which has one or more apertures, each containing an elastic member. The elastic member has an insertion hole at a dimension slightly smaller than an electronic element being held therein.

Next, a guiding plate is provided to direct each electronic element in the insertion hole with the elastic member firmly holding the electronic element in which a plating seed layer is to be formed in the insertion hole, and with two ends of the electronic element exposed outside the holding plate.

Finally form a metal film on the surface of the electronic element through a semiconductor manufacturing process (such as sputtering, vapor vaporization, chemical vapor vaporization, or the like). The metal film thus formed is the seed layer ready for plating, to form signal contacts or a circuit layout.

Using sputtering or vapor vaporization to form the plating seed layer can save the processes of dipping the surface of the electronic element in a metal solution and sintering that occur to the conventional techniques. Not only the entire process for manufacturing the plating seed layer is simpler, total manufacturing cost also may be reduced. This is a great improvement over the conventional techniques to form the plating seed layer.

The foregoing, as well as additional objects, features and advantages of the invention will be more readily apparent from the following detailed description, which proceeds with reference to the accompanying drawings.

### BRIEF DESCRIPTION OF THE DRAWINGS

FIGS. 1A through 1C are schematic views of conventional manufacturing processes for forming a plating seed layer on a multilayer ceramic capacitor;

FIGS. 2A through 2C are schematic views of manufacturing processes for forming a plating seed layer on an electronic element according to the invention; and

FIGS. 3A through 3E are schematic views of detailed manufacturing processes shown in FIG. 2B for inserting an electronic element in an insertion hole of a holding plate.

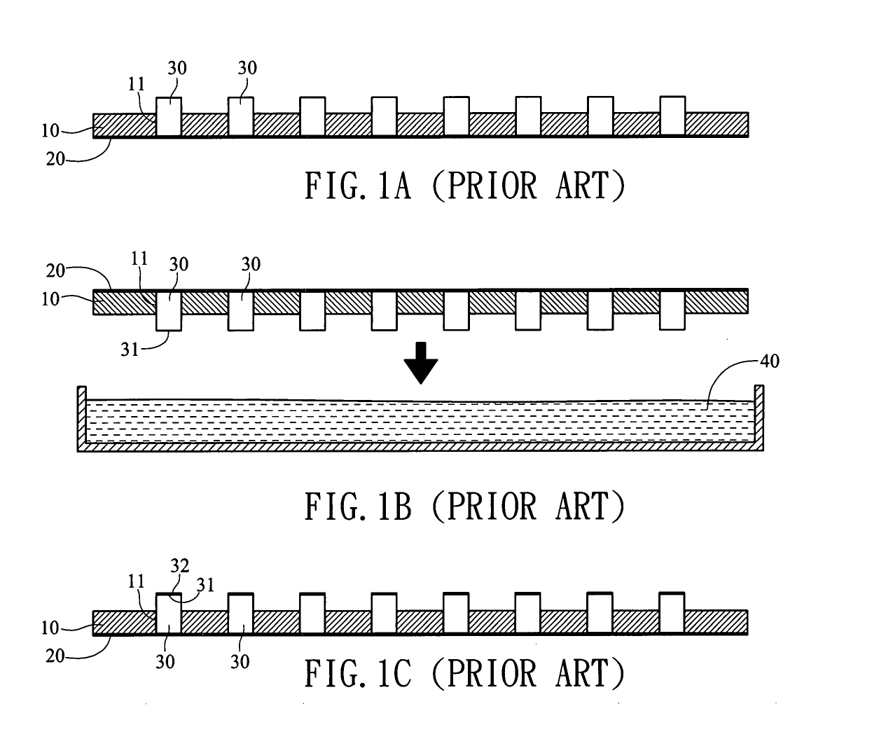

### DESCRIPTION OF THE PREFERRED EMBODIMENTS

The method for manufacturing a plating seed layer of electronic elements of the invention is adopted for use in forming a plating seed layer on electronic elements made from multi-layer ceramics such as capacitors, inductors, resistors and the like.

The main concept of the invention is, first, to direct electronic elements in which a plating seed layer is to be formed in a holding plate through a guiding plate. The holding plate has elastic members to hold the electronic elements firmly with two ends of the electronic elements exposed outside the holding plate. Next, form a metal film on the surfaces of the two ends of the electronic elements through a semiconductor manufacturing process to become seed layers for plating. Then proceed a plating process to form required signal contacts or a circuit layout on the surfaces of the electronic elements.

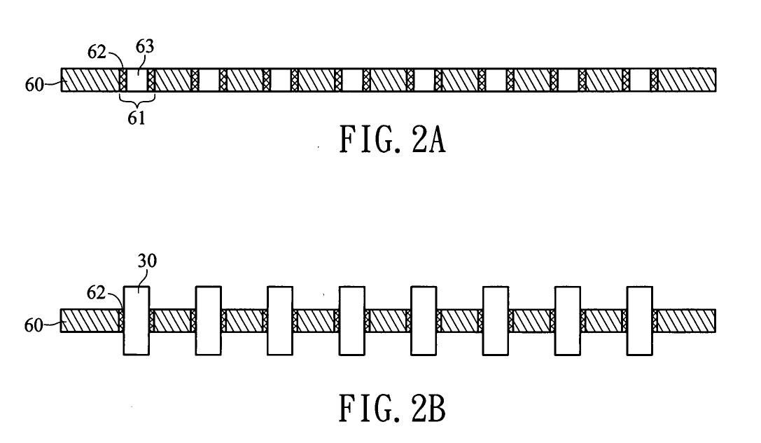

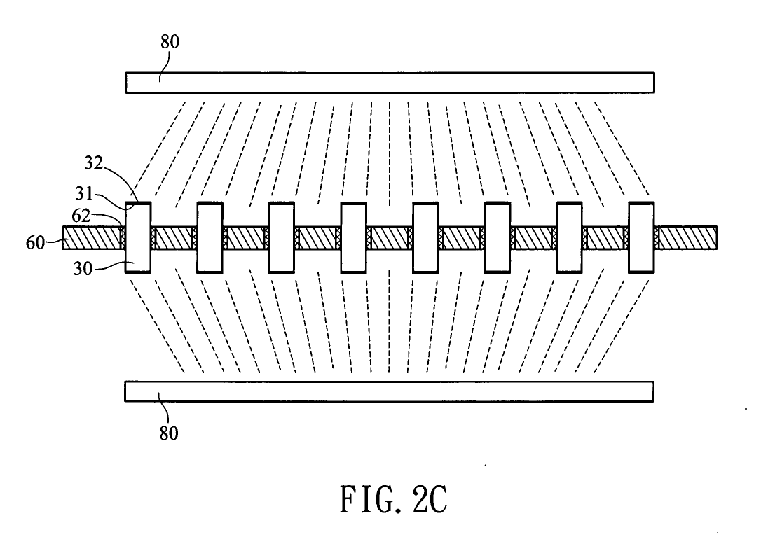

Refer to FIGS. 2A through 2C for the manufacturing processes to form a plating seed layer on electronic elements according to the invention.

First, as shown in FIG. 2A, provide a holding plate 60, which has one or more apertures 61, each having an elastic member 62 located therein. The elastic member 62 has an insertion hole 63, which is formed in a dimension slightly smaller than the dimension of an electronic element to be held therein.

Referring to FIG. 2B, the electronic element 30 in which a plating seed layer is to be formed is inserted into the insertion hole 63 of the holding plate 60. Since the insertion hole 63 is slightly smaller than the electronic element, the electronic element 30 is firmly held by the elastic member 62 in the aperture 61. The electronic element 30 has two ends exposed outside the holding plate 60 for plating.

Finally, referring to FIG. 2C, form a metal film on the surfaces of electronic element 30 through a semiconductor manufacturing process. The metal film thus formed is a seed layer 32 of the electronic element 30. The metal film may be formed by sputtering with atoms of a target substance 80 bouncing out and depositing on the surfaces of the two ends of the electronic element 30 that are exposed outside the holding plate 70 to form the seed layer 32. Of course the metal film may also be formed on the surface of only one end of the electronic element 30 according to the requirements. After the seed layer 32 is formed, the plating process of the downstream operation may be performed.

Besides sputtering, the seed layer 32 on the surfaces of the electronic element 30 may also be formed by vapor vaporization, chemical vapor vaporization or the like.

The material of the seed layer 32 is selected according to the plating metal. It is generally silver (Ag), copper (Cu), nickel and chrome alloy (Ni/Cr alloy), or the like.

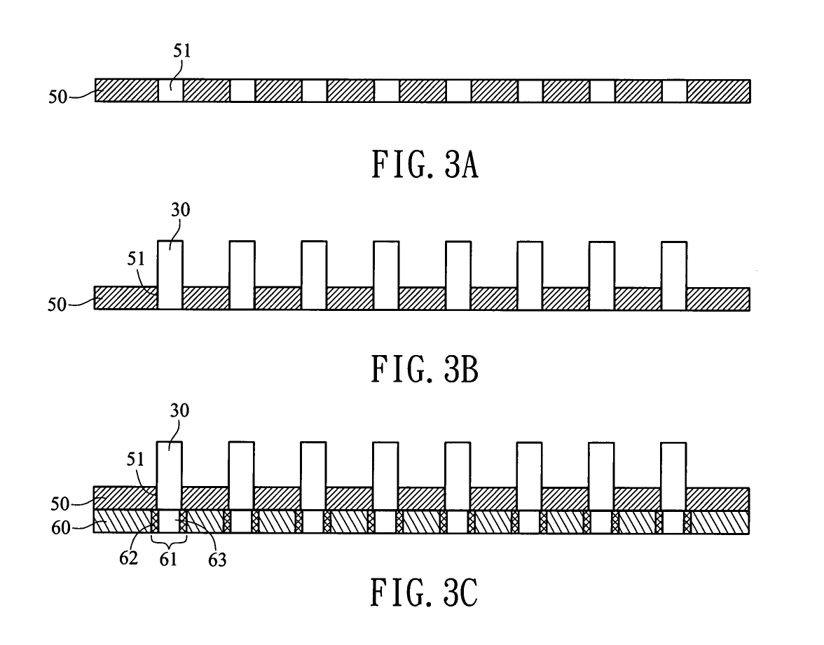

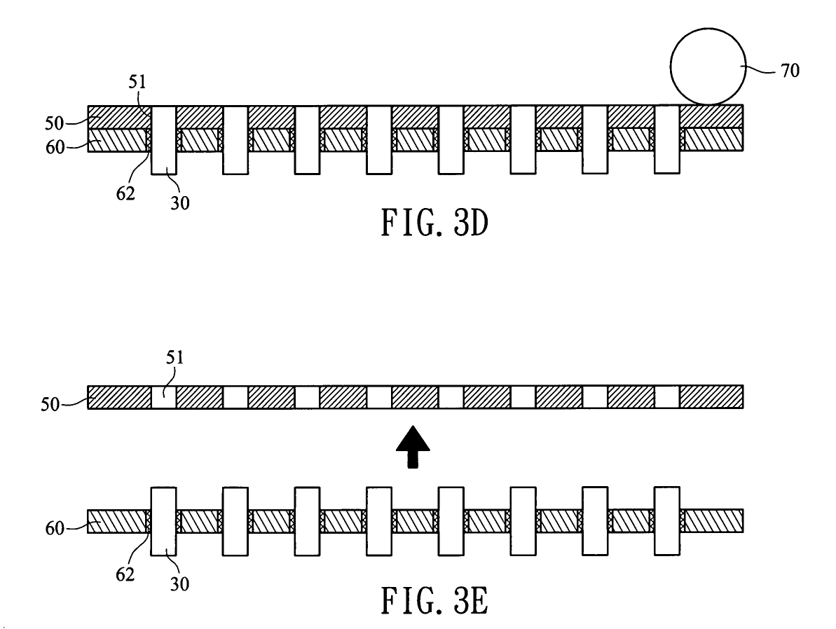

Refer to FIGS. 3A through 3E for the detailed manufacturing processes shown in FIG. 2B for inserting the electronic element 30 into the insertion hole 62 of the holding plate 60.

First, as shown in FIG. 3A, provide a guiding plate 50, which has one or more holding apertures 51 at a dimension proximate to the size of the aperture 61 of the holding plate 60. The holding apertures 51 are spaced from each other at a distance same as that of the aperture 61.

Next, referring to FIG. 3B, insert each electronic element 30 into the holding aperture 51.

Next, referring to FIG. 3C, place the guiding plate 50, which has the electronic element 30 located on the holding plate 60 and align each holding aperture 51 with each insertion aperture 63.

Then, referring to FIG. 3D, roll a roller 70 over the surface of the entire guiding plate 50, to push the electronic element 30 held in the holding aperture 51 into the insertion hole 63 of the holding plate 60. The elastic member 62 can hold the electronic element 30 firmly with two ends of the electronic element 30, exposed outside the holding plate 60.

Finally, as shown in FIG. 3E, separate the guiding plate 50 and the holding plate 60 to form the structure shown in FIG. 2B. Then form the seed layer 32 on the surface of the electronic element 30 through the semiconductor manufacturing process.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments, which do not depart from the spirit and scope of the invention.

What is claimed is:

1. A method for manufacturing a plating seed layer of electronic elements to manufacture a seed layer for plating on an electronic element, comprising the steps of:
providing a holding plate which has at least one aperture containing an elastic member, the elastic member having an insertion hole for holding the electronic element;
inserting the electronic element into the insertion hole, the electronic element being held firmly by the elastic member, and the electronic element having two ends exposed outside the holding plate; and
forming a metal film on surfaces of the electronic element through a semiconductor manufacturing process to become the plating seed layer.

2. The method of claim 1, wherein the step of inserting the electronic element into the insertion hole, the electronic element being held firmly by the elastic member, and the electronic element having two ends exposed outside the holding plate further includes the steps of:
providing a guiding plate which has at least one holding aperture at a dimension substantially same as that of the aperture;
directing the electronic element into the holding aperture;
placing the guiding plate on the holding plate, and aligning the holding aperture with the insertion hole;
rolling a roller over the electronic element to insert the electronic element held in the holding aperture into the insertion hole with the two ends of the electronic element exposing outside the holding plate; and
separating the guiding plate and the holding plate.

3. The method of claim 1, wherein the step of forming a metal film on surfaces of the electronic element through a semiconductor manufacturing process to become the plating seed layer is accomplished by sputtering.

4. The method of claim 1, wherein the step of forming a metal film on surfaces of the electronic element through a semiconductor manufacturing process to become the plating seed layer is accomplished by vapor vaporization.

5. The method of claim 1, wherein the step of forming a metal film on surfaces of the electronic element through a semiconductor manufacturing process to become the plating seed layer is accomplished by chemical vapor vaporization.

6. The method of claim 1, wherein the step of forming a metal film on surfaces of the electronic element through a semiconductor manufacturing process to become the plating seed layer is formed the metal film on the surface of one end of the electronic element.

7. The method of claim 1, wherein the step of forming a metal film on surfaces of the electronic element through a semiconductor manufacturing process to become the plating seed layer is formed the metal film on the surfaces of the two ends of the electronic element.

8. The method of claim 1, wherein the material of the metal film is selected from the group consisting of silver, copper, nickel and chrome alloy.
